(19) United States
(12) Patent Application Publication
(10) Pub. No.: US 2025/0383604 A1
(43) Pub. Date: Dec. 18, 2025

(54) SUBSTRATE TREATMENT METHOD AND SUBSTRATE TREATMENT APPARATUS

(71) Applicant: Tokyo Electron Limited, Tokyo (JP)

(72) Inventors: Kohei YAZAKI, Nirasaki City (JP); Kazuya DOBASHI, Nirasaki City (JP); Seiji NAGAHARA, Tokyo (JP)

(21) Appl. No.: 19/229,541

(22) Filed: Jun. 5, 2025

(30) Foreign Application Priority Data
Jun. 17, 2024 (JP) 2024-097257

(51) Int. Cl. G03F 7/16

(52) U.S. Cl. CPC G03F 7/168

(57) ABSTRACT

A substrate treatment method includes: (A) preparing a substrate; (B) supplying a metal oxide resist material containing at least any one of a cluster in which metals are three-dimensionally bonded and a precursor of the cluster and an inhibitor containing metal, to the substrate; and (C) causing the at least any one of the cluster and the precursor to react with the inhibitor to form a resist film containing a polymer in which metals in the metal oxide resist material are linked in a chain.

### CROSS REFERENCE TO RELATED APPLICATIONS

This application is based upon and claims the benefit of priority of the prior Japanese Patent Application No. 2024-97257, filed in Japan on Jun. 17, 2024, the entire contents of which are incorporated herein by reference.

### TECHNICAL FIELD

This disclosure relates to a substrate treatment method and a substrate treatment apparatus.

### BACKGROUND

Japanese Translation of PCT International Application Publication No. 2022-541818 discloses the pattern formation with UV light and EUV light using organotin sulfide (and selenide) cluster.

### SUMMARY

An aspect of this disclosure is a substrate treatment method including: (A) preparing a substrate; (B) supplying a metal oxide resist material containing at least any one of a cluster in which metals are three-dimensionally bonded and a precursor of the cluster and an inhibitor containing metal, to the substrate; and (C) causing the at least any one of the cluster and the precursor to react with the inhibitor to form a resist film containing a polymer in which metals in the metal oxide resist material are linked in a chain.

### BRIEF DESCRIPTION OF THE DRAWINGS

FIG. 1 is an explanatory view illustrating the outline of an internal configuration of a wafer treatment apparatus as a substrate treatment apparatus according to an embodiment.

FIG. 2 is a view illustrating the outline of an internal configuration on the front side of a wet treatment section.

FIG. 3 is a view illustrating the outline of an internal configuration on the rear side of the wet treatment section.

FIG. 4 is a chart for explaining an example of a metal oxide resist material.

FIG. 5 is a chart for explaining examples of the metal oxide resist material.

FIG. 6 is a chart for explaining examples of an inhibitor.

FIG. 7 is a chart for explaining examples of the inhibitor.

FIG. 8 is a chart for explaining a polymer in which metals in the metal oxide resist material are linked in a chain.

FIG. 9 is a chart for explaining a polymer in which metals in the metal oxide resist material are linked in a chain.

FIG. 10 is a view schematically illustrating a cross section at a delivery block portion of the wafer treatment apparatus in FIG. 1.

FIG. 11 is a flowchart illustrating main processes in Example 1 of a treatment sequence.

FIG. 12 is a chart for explaining a state of an exposed portion of a film of the metal oxide resist.

FIG. 13 is a view for explaining the effect according to this disclosure.

FIG. 14 is a view for explaining the effect according to this disclosure.

FIG. 15 is a flowchart illustrating main processes in Example 2 of the treatment sequence.

FIG. 16 is a flowchart illustrating main processes in Example 3 of the treatment sequence.

FIG. 17 is a view illustrating a configuration example of a resist supply module applicable to Example 1 of the treatment sequence.

FIG. 18 is a view illustrating a configuration example of a resist supply module applicable to Examples 1, 2 of the treatment sequence and a modification of Example 2.

FIG. 19 is a view illustrating another configuration example of the resist supply module when Example 1 of the treatment sequence is applied.

FIG. 20 is a view illustrating a configuration example of the resist supply module applicable to Example 3 of the treatment sequence.

FIG. 21 is a flowchart illustrating main processes in Example 4 of the treatment sequence.

FIG. 22 is a flowchart illustrating main processes in Example 5 of the treatment sequence.

FIG. 23 is a view illustrating a configuration example of a resist supply module applicable to Example 4 and Example 5 of the treatment sequence and modifications thereof.

### DETAILED DESCRIPTION

Hereinafter, a configuration of a substrate treatment apparatus according to this embodiment will be explained with reference to the drawings. Note that, in this description, the same reference codes denote components having substantially the same functional configurations to omit duplicate explanations.

### <Wafer Treatment Apparatus>

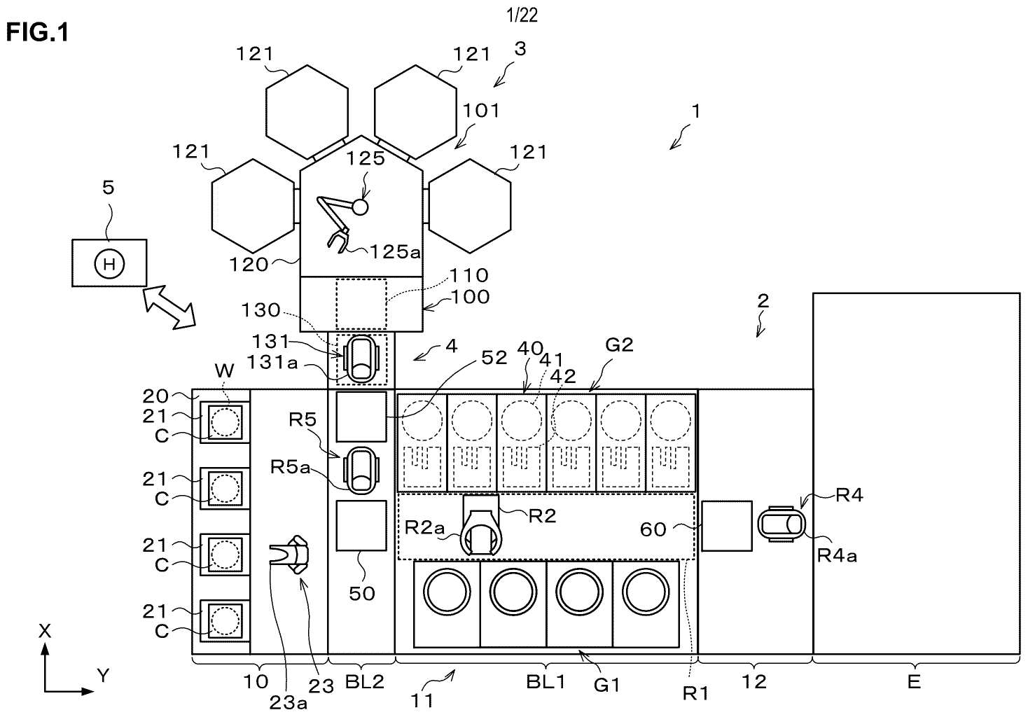

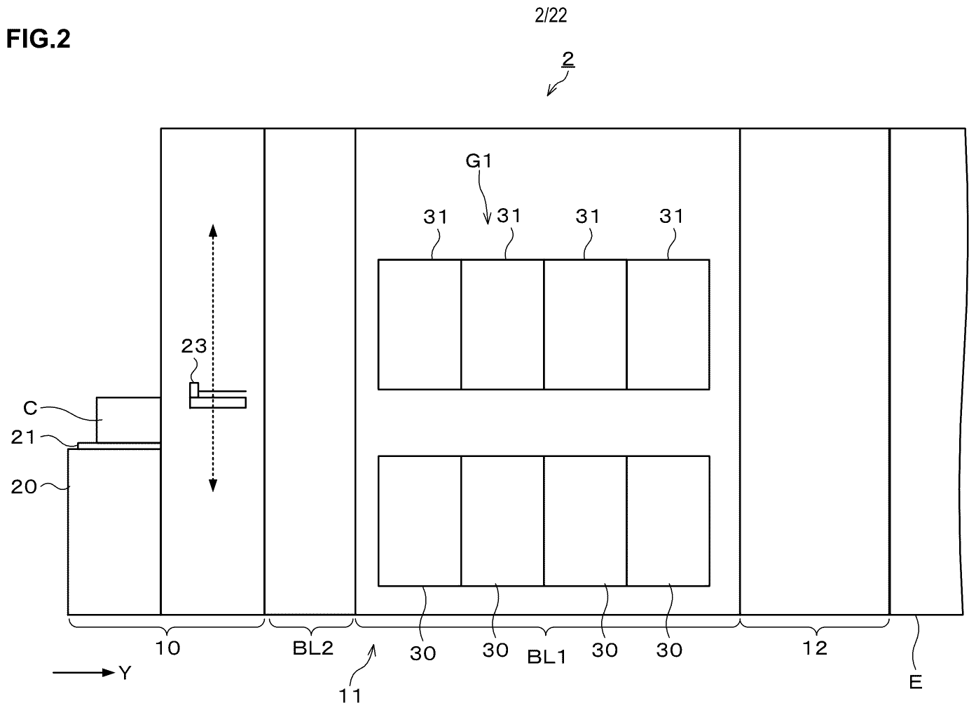

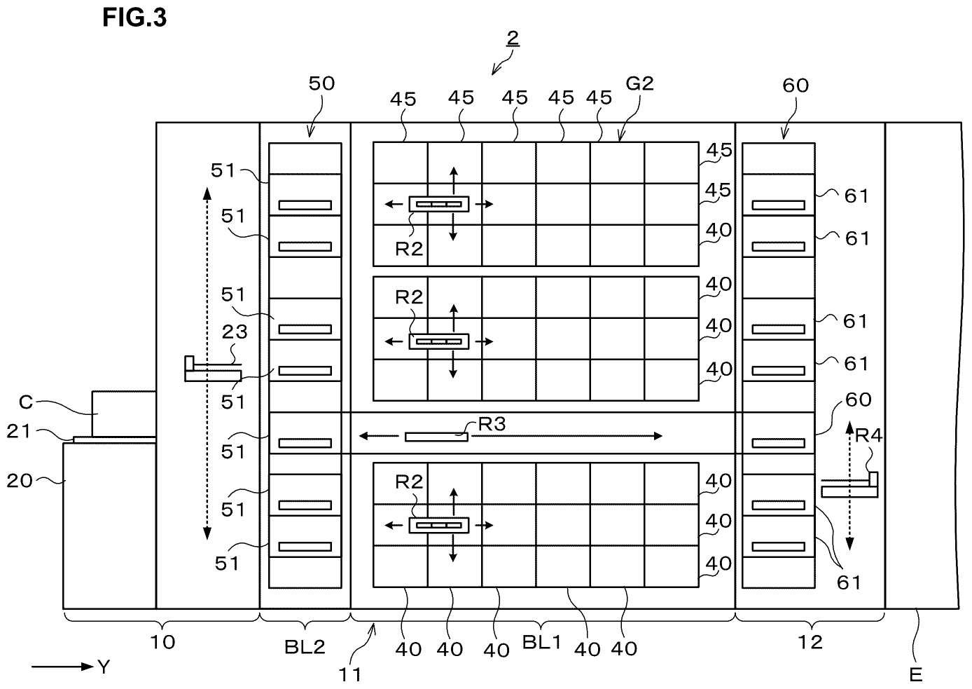

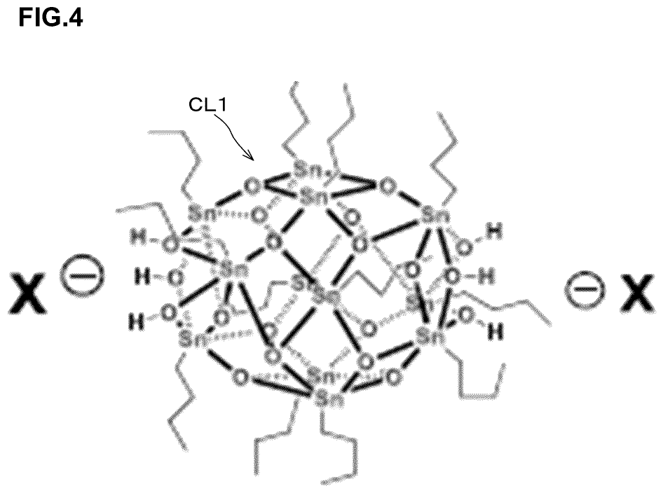

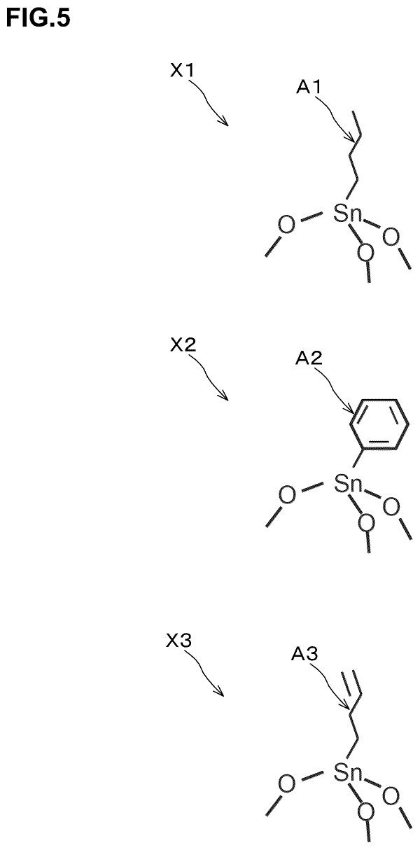

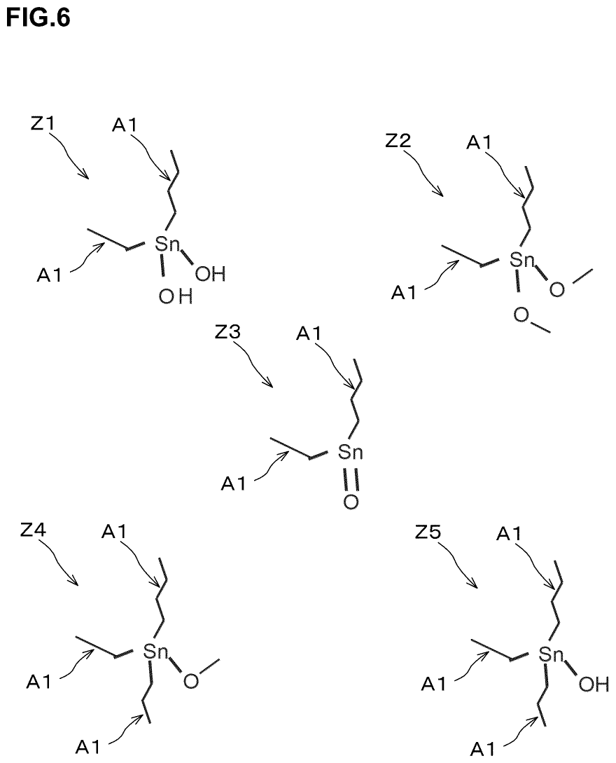

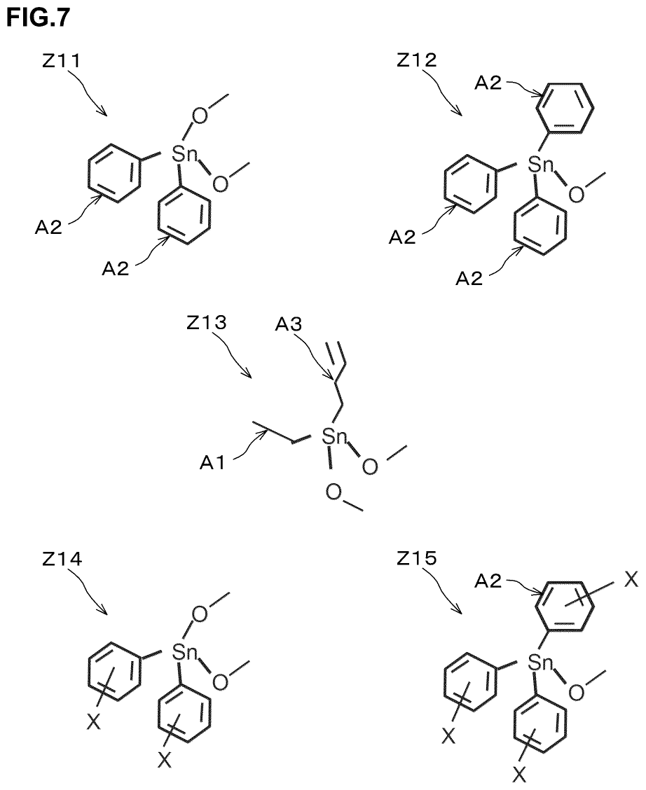

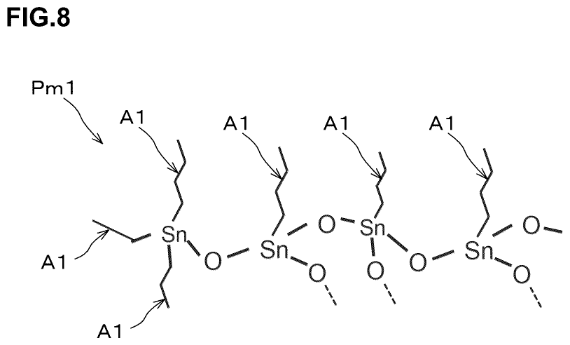

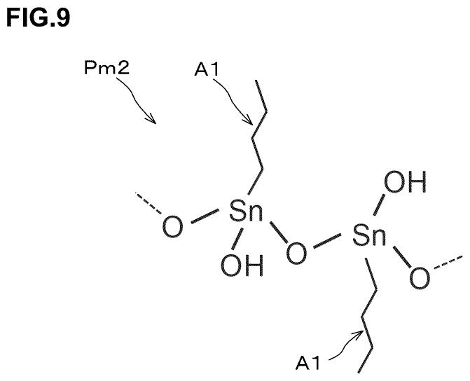

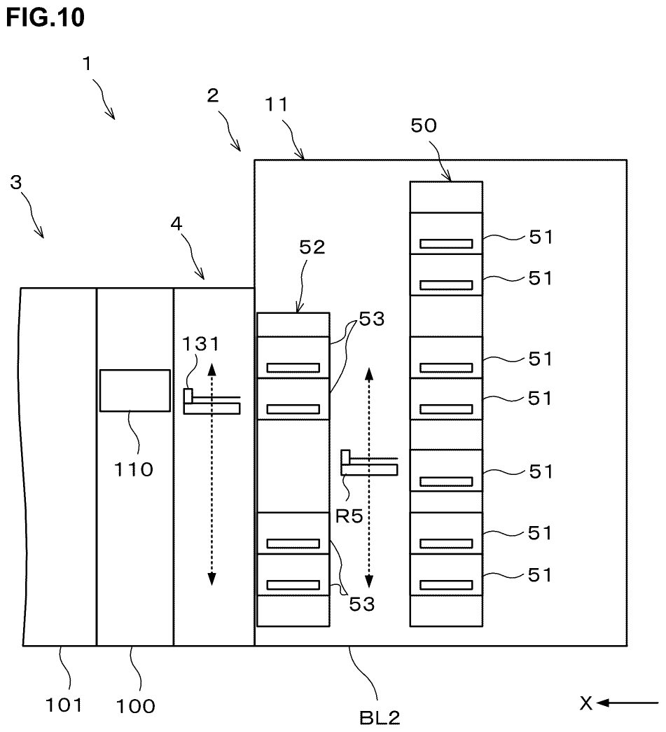

FIG. 1 is an explanatory view illustrating the outline of an internal configuration of a wafer treatment apparatus as a substrate treatment apparatus according to this embodiment. FIG. 2 and FIG. 3 are views illustrating the outline of an internal configuration on the front side and the rear side of a later-explained wet treatment section, respectively. FIG. 4 and FIG. 5 are charts each for explaining examples of a metal oxide resist material. FIG. 6 and FIG. 7 are charts each for explaining examples of an inhibitor. FIG. 8 and FIG. 9 are charts each for explaining a polymer in which metals in the metal oxide resist material are linked in a chain. FIG. 10 is a view schematically illustrating a cross section at a later-explained delivery block portion of the wafer treatment apparatus in FIG. 1.

The wafer treatment apparatus 1 in FIG. 1 forms a film of the metal oxide resist on a semiconductor wafer (hereinafter, referred to as a “wafer”)) W as a substrate. Specifically, the wafer treatment apparatus 1 forms a film of the metal oxide resist, then performs, on the wafer W subjected to exposure processing of transferring a pattern of a mask to the film of the metal oxide resist, a heat treatment (PEB treatment) after the exposure processing, and further develops the wafer W subjected to the PEB treatment. Thus, a pattern of the metal oxide resist is formed. Note that the above metal oxide resist is, for example, negative type and for EUV (Extreme Ultra-Violet) light, that is, has sensitivity to EUV light. Besides, the metal contained in the metal oxide resist is optional, and is tin in this embodiment but may be hafnium, tellurium, bismuth, indium, antimony, iodine, germanium, a combination of them including tin or the like.

The wafer treatment apparatus 1 includes, for example, a wet (liquid phase) treatment section 2, a dry (gas phase) treatment section 3, and a relay carrier section 4.

The wet treatment section 2 includes a cassette station 10, a treatment station 11, and an interface station 12, and is coupled to an exposure apparatus E as illustrated in FIG. 1 to FIG. 3. The exposure apparatus E performs exposure processing on the wafer W, specifically, performs the exposure processing using, for example, EUV light. In the wet treatment section 2, the cassette station 10, the treatment station 11, and the interface station 12 are integrally connected.

Note that a coupling direction of the wet treatment section 2 and the exposure apparatus E is called a width direction, and a direction perpendicular to the coupling direction, namely, the width direction in top view is called a depth direction in the following.

To/from the cassette station 10 in the wet treatment section 2, a cassette C that is a housing container configured to be able to house a plurality of wafers W is carried in/out.

In the cassette station 10, a cassette stage 20 is provided, for example, at an end portion on a width direction one side (Y-direction negative side in FIG. 1 and so on). On the cassette stage 20, a plurality of, for example, four stage plates 21 are provided. The stage plates 21 are provided side by side in a row in the depth direction (X-direction in FIG. 1). On the stage plates 21, the cassettes C can be mounted when the cassettes C are carried in/out from/to the outside of the wet treatment section 2.

Further, in the cassette station 10, a carrier module 23 which carries the wafer W is provided, for example, on a width direction other side (Y-direction positive side in FIG. 1). The carrier module 23 has a carrier arm 23a configured to be movable in the depth direction (X-direction in FIG. 1). Further, the carrier arm 23a of the carrier module 23 is configured to be movable also in a vertical direction and a direction around a vertical axis. The carrier module 23 can carry the wafer W between the cassette C on each of the stage plates 21 and a delivery module 51 in a later-explained delivery tower 50.

The treatment station 11 includes a plurality of various treatment modules which perform predetermined treatments such as a developing treatment and the like on the wafer W.

The treatment station 11 is divided into a plurality of (two in the example in the drawing) blocks each including various modules. A treatment block BL1 is provided on the interface station 12 side, and a delivery block BL2 is provided on the cassette station 10 side.

The treatment block BL1 has, for example, a first block G1 on a front side (X-direction negative side in FIG. 1) and a second block G2 on a deep side (X-direction positive side in FIG. 1).

For example, in the first block G1, as illustrated in FIG. 2, a plurality of solution treatment modules, for example, developing modules 30 and resist supply modules 31 are arranged in this order from the bottom.

The developing module 30 is a wet developer which develops the wafer W in a wet manner. In other words, the developing module 30 develops the wafer W with the developing solution (specifically, a nonpolar developing solution) as a developing material. The nonpolar developing solution is, for example, butyl acetate, 2-heptanone, PEGMEA, or a mixture of one of them and an organic acid.

The resist supply module 31 serves as both of the following first supplier and second supplier.

The first supplier supplies the metal oxide resist material to the wafer W. In this embodiment, the resist supply module 31 as the first supplier supplies liquid of the metal oxide resist material to the wafer W, namely, performs the supply of the metal oxide resist material to the wafer W in a wet manner. Specifically, the resist supply module 31 supplies the liquid of the metal oxide resist material to the wafer W so that the entire surface of the wafer W is covered with the liquid of the metal oxide resist material.

The metal oxide resist material is, for example, a material containing a cluster in which metals are three-dimensionally bonded, namely, a particle, and is specifically a material containing a cluster CL1 having a three-dimensional network structure of tin (Sn) and oxygen (O) as illustrated in FIG. 4. The cluster CL1 in FIG. 4 is expressed by Expression [(Ligand Sn)₁₂O₁₄(OH)₆]Xₙ.

The metal oxide resist material may contain a precursor of the cluster in place of or in addition to the above cluster. In other words, the metal oxide resist material contains at least any one of the cluster and its precursor.

Further, at least any one of the cluster and its precursor contained in the metal oxide resist material has a structure in which one carbon is directly bonded to the metal. Specifically, the at least any one of the cluster and its precursor contained in the metal oxide resist material has a structure in which one carbon is directly bonded to the metal and the carbon constitutes an alkyl group, an aryl group, an alkenyl group, or the like.

More specifically, the at least any one of the cluster and its precursor contained in the metal oxide resist material has the following structure which is possessed by a monoalkyl tin compound exemplified by a code X1, a monoaryl tin compound exemplified by a code X2, and a monoalkenyl tin compound exemplified by a code X3 in FIG. 5. In other words, the at least any one of them has the structure in which a hydrocarbon group such as an alkyl group A1, an aryl group A2, an alkenyl group A3, or the like is directly bonded to one tin (Sn) atom and an oxygen (O) atom is directly bonded to a portion other than the hydrocarbon group in the tin atom.

Note that the precursor of the cluster contained in the metal oxide resist material may be the monoalkyl tin compound, the monoaryl tin compound, and the monoalkenyl tin compound exemplified by the codes X1 to X3 in FIG. 5.

The second supplier supplies an inhibitor containing metal to the wafer W. In this embodiment, the resist supply module 31 as the second supplier supplies liquid of the inhibitor to the wafer W and performs the supply of the inhibitor to the wafer W in a wet manner. For example, the resist supply module 31 supplies the liquid of the inhibitor to the entire surface of the wafer W.

Further, the resist supply module 31 as the second supplier may supply gas of the inhibitor to the wafer W, specifically, may supply the gas of the inhibitor to the wafer W under an atmosphere at an atmospheric pressure or higher.

The inhibitor prevents the cluster from remaining on the wafer W.

Specifically, in the case where the metal oxide resist material contains the cluster itself, the inhibitor promotes generation of a polymer in which the metals in the material are linked in a chain while decomposing the cluster in the metal oxide resist material supplied to the wafer W.

Besides, in the case where the metal oxide resist contains the precursor of the cluster, the inhibitor promotes generation of a polymer in which the metals in the material are linked in a chain while preventing the precursors in the metal oxide resist material supplied to the wafer W from bonding together to become a cluster.

The inhibitor contains, for example, the same metal as the metal in the at least any one of the cluster and its precursor contained in the metal oxide resist material. The polymer generated by the inhibitor becomes the one in which the metals contained in both the at least any one of the cluster and its precursor and the inhibitor are linked in a chain. In other words, the inhibitor also becomes the raw material of the above polymer, so that not only the metal in the at least any one of the cluster and its precursor but also the metal in the inhibitor that is the same as the former metal are contained in the polymer to be generated by the inhibitor.

However, the at least any one of the cluster and its precursor contained in the metal oxide resist material has a structure in which one carbon is directly coupled to the metal, whereas the inhibitor contains a compound having a structure in which two or more carbons are directly coupled to the metal. Further, the carbon directly coupled to the metal in the compound contained in the inhibitor constitutes an alkyl group, an aryl group, an alkenyl group, or the like.

For example, the inhibitor contains at least any one of a dialkyl tin compound, a trialkyl tin compound, and a diaryl tin compound, and, a triaryl tin compound, a dialkenyl tin compound, and a trialkenyl tin compound. Further, in the tin compound contained in the inhibitor, carbons of a plurality of types of organic groups may be directly coupled to tin (Sn) atoms and, for example, carbons of the alkyl group and the alkenyl group may be directly coupled to tin atoms.

Further, in the dialkyl tin compound contained in the inhibitor, a tin (Sn) atom in the compound is bonded to oxygen (O) atoms in a portion other than the alkyl groups A1 being hydrocarbon groups as exemplified by codes Z1 to Z3 in FIG. 6.

Similarly, in the trialkyl tin compound contained in the inhibitor, tin (atom) in the compound is bonded to an oxygen (O) atom in a portion other than the alkyl groups A1 being hydrocarbon groups as exemplified by codes Z4, Z5 in FIG. 6.

Further, similarly, in the diaryl tin compound contained in the inhibitor, tin (atom) in the compound is bonded to oxygen (O) atoms in a portion other than the aryl groups A2 being hydrocarbon groups as exemplified by a code Z11 in FIG. 7.

Further, similarly, in the triaryl tin compound contained in the inhibitor, tin (atom) in the compound is bonded to an oxygen (O) atom in a portion other than the aryl groups A2 being hydrocarbon groups as exemplified by a code Z12 in FIG. 7.

Further, similarly, in the tin compound contained in the inhibitor in which carbons of the alkyl group and the alkenyl group are directly bonded to tin (atom), a tin (Sn) atom is bonded to oxygen (O) atoms in a portion other than the alkyl group A1 and the alkenyl group A3 being hydrocarbon groups as exemplified by a code Z13 in FIG. 7.

Note that the organic groups bonded to a tin (atom) in the tin compound contained in the inhibitor may be halogenated ones (halogenated aryl groups in the example of the drawing) as in compounds Z14, Z15 in FIG. 7.

Further, the inhibitor may contain another solvent of a compound having a structure in which two or more carbons are directly bonded to the metal. Specifically, when the compound having the structure in which two or more carbons are directly bonded to the metal is liquid, the inhibitor may be the one made by diluting the liquid with the solvent.

For example, the developing module 30 and the resist supply module 31 are arranged four each side by side in the width direction (Y-direction in the drawing) as illustrated in FIG. 2. Note that the numbers and the arrangements of the developing modules 30 and the resist supply modules 31 can be arbitrarily selected.

In each of the developing module 30 and the resist supply module 31, a predetermined treatment solution is supplied onto the wafer W, for example, by the spin coating method. In the spin coating method, the treatment solution is discharged onto the wafer W, for example, from a discharge nozzle (not illustrated) and the wafer W is rotated to diffuse the treatment solution over the surface of the wafer W. In the developing module 30, a liquid film (paddle) of the developing solution is formed to develop the wafer W.

For example, in the second block G2, as illustrated in FIG. 3, a plurality of thermal treatment modules 40 and ultraviolet irradiation modules 45 are provided side by side in the vertical direction (up-down direction in the drawing) and the width direction (Y-direction in the drawing). The numbers and the arrangements of the thermal treatment modules 40 and the ultraviolet irradiation modules 45 can also be arbitrarily selected.

For example, at least some of the thermal treatment modules 40 are the ones in each of which a heating section for heating the wafer W and a cooling section for cooling the wafer W are coupled. In the thermal treatment module 40, the heating section has a hot plate 41 and the cooling section has a cooling plate 42 as illustrated in FIG. 1. The hot plate 41 is configured such that the wafer W is mounted thereon, and is provided with a heating means such as a resistance heater therein. The cooling plate 42 is configured such that the wafer W is mounted thereon, and is provided with a cooling means such as a flow path for a cooling refrigerant therein.

Further, some of the thermal treatment modules 40 are used for a pre-applied bake (PAB) treatment and other some of them are used for a heat treatment (PEB treatment) after the exposure processing. The thermal treatment module 40 used for the PAB treatment constitutes the following reactor. The reactor forms a film of the metal oxide resist containing the polymer in which metals in the metal oxide resist material are linked in chains, by causing the at least any one of the cluster and its precursor contained in the metal oxide resist material to react with the inhibitor on the wafer W.

The reactor disrupts the balance of a stable structure of the cluster by bonding the metal (tin (Sn) in the example of the drawing) constituting the cluster with the inhibitor having the same metal to generate an amorphous polymer, for example, as exemplified by a code Pm1 in FIG. 8.

Further, the reactor can also generate a polymer in which metals (tin (Sn) in the example of the drawing) contained in both the metal oxide resist material and the inhibitor are coupled in a chain via oxygen (O) without forming the cluster, for example, as exemplified by a code Pm2 in FIG. 9.

The ultraviolet irradiation module 45 performs ultraviolet irradiation processing on the wafer W. The ultraviolet irradiation processing is processing for irradiating the entire upper surface, namely, the entire surface of the wafer W with an ultraviolet ray, specifically, processing for irradiating the entire surface of the wafer W with an ultraviolet ray in an inert gas atmosphere and without a mask. Note that the “entire surface of the wafer W” includes at least the entire device formation region of the wafer W.

The treatment block BL1 is provided with, as illustrated in FIG. 1, a carrier path R1 extending in the width direction at a portion between the first block G1 and the second block G2. In the treatment block BL1, a plurality of developing modules 30 and resist supply modules 31 are arranged side by side along the carrier path R1 extending in the width direction. In the carrier path R1, a carrier module R2 which carries the wafer W is arranged.

The carrier module R2 has a carrier arm R2a movable, for example, in the width direction (Y-direction in FIG. 1), the vertical direction, and the direction around the vertical axis. The carrier module R2 can move the carrier arm R2a holding the wafer W in the carrier path to carry the wafer W to a predetermined apparatus in the first block G1, the second block G2, and later-explained delivery tower 50 and delivery tower 60 therearound. A plurality of the carrier modules R2 are arranged, for example, one above the other as illustrated in FIG. 3, and can carry the wafers W, for example, to predetermined modules at similar heights in the first block G1, the second block G2, and the delivery towers 50, 60.

Further, in the carrier path R1, a shuttle carrier module R3 is provided which linearly carries the wafer W between the delivery tower 50 and the delivery tower 60.

The shuttle carrier module R3 can linearly move the supported wafer W in the Y-direction to carry the wafer W between the apparatus in the delivery tower 50 and the apparatus in the delivery tower 60 at similar heights.

In the delivery block BL2, as illustrated in FIG. 1, the delivery tower 50 is provided at the middle portion in the depth direction (X-direction in the drawing). The delivery tower 50 is specifically provided at a position, in the delivery block BL2, adjacent in the width direction (Y-direction in the drawing) to the carrier path R1 in the treatment block BL1. In the delivery tower 50, as illustrated in FIG. 3, a plurality of delivery modules 51 are provided in a manner to be piled up in the vertical direction.

The interface station 12 is provided between the treatment station 11 and the exposure apparatus E as illustrated in FIG. 1 and delivers the wafer W between them.

At a position, in the interface station 12, adjacent in the width direction (Y-direction in the drawing) to the carrier path R1 in the treatment block BL1, the delivery tower 60 is provided. In the delivery tower 60, as illustrated in FIG. 3, a plurality of delivery modules 61 are provided in a manner to be piled up in the vertical direction.

Further, as illustrated in FIG. 1, a carrier module R4 is provided in the interface station 12.

The carrier module R4 is provided at a position adjacent in the width direction (Y-direction in the drawing) to the delivery tower 60, and has a carrier arm R4a which is movable, for example, in the depth direction (X-direction in FIG. 1), the vertical direction, and the direction around the vertical axis. The carrier module R4 can carry the wafer W between the plurality of delivery modules 61 in the delivery tower 60 and the exposure apparatus E, while holding the wafer W by the carrier arm R4a.

Further, the delivery block BL2 in the treatment station 11 has, as illustrated in FIG. 1, a delivery tower 52 at the end portion on the deep side (X-direction positive side in the drawing).

The delivery tower 52 has a delivery module 53 as illustrated in FIG. 10. In the delivery tower 52, a plurality of delivery modules 53 may be provided so as to be piled up in the vertical direction (up-down direction in FIG. 10).

Furthermore, a carrier module R5 is provided in the delivery block BL2 as illustrated in FIG. 1. The carrier module R5 is provided between the delivery tower 50 and the delivery tower 52, and has a carrier arm 5a movable, for example, in the vertical direction and the direction around the vertical axis. The carrier module R5 can carry the wafer W between the plurality of delivery modules 51 in the delivery tower 50 and the plurality of delivery modules 53 in the delivery tower 52, while holding the wafer W by the carrier arm 5a.

The dry treatment section 3 has, for example, a load lock station 100 and a treatment station 101 as illustrated in FIG. 1. In the dry treatment section 3, the load lock station 100 and the treatment station 101 are integrally connected. In this example, the coupling direction of the load lock station 100 and the treatment station 101 and the coupling direction of the wet treatment section 2 and the exposure apparatus E are perpendicular in top view.

In the load lock station 100, a load lock module 110 is provided which is configured to be able to switch the inside atmosphere between a reduced-pressure atmosphere and the atmospheric-pressure atmosphere.

The treatment station 101 has, for example, a vacuum carrier chamber 120 and a plurality of developing modules 121.

The vacuum carrier chamber 120 is composed of a housing configured to be sealable, and its inside is kept in a reduced-pressure state (vacuum state). The vacuum carrier chamber 120 is formed, for example, in an almost polygonal shape (pentagon in the example of the drawing) in top view.

The developing module 121 is a dry developer which develops the wafer W in a dry manner. The wet manner is a manner using at least liquid for the wafer, whereas the dry manner is a manner of using gas without using liquid for the wafer W, specifically, a manner of using gas without using liquid under a reduced pressure. The gas for development as the developing material used by the developing module 121 is polar gas containing, for example, halogen (element) such as bromine, more specifically, bromine trichloride (BrCl₃).

For example, in the treatment station 101, a plurality of (four in the example of the drawing) developing modules 121 and the load lock station 100 are arranged in a manner to surround the vacuum carrier chamber 120 in top view, namely, to line up around the vertical axis passing through the central portion of the vacuum carrier chamber 120.

The treatment station 101 may have a thermal treatment module (not illustrated). The thermal treatment module heats the wafer W, namely, performs a heat treatment on the wafer W.

Further, inside the vacuum carrier chamber 120, a carrier module 125 which carries the wafer W is provided. The carrier module 125 has a carrier arm 125a movable, for example, in the direction around the vertical axis. The carrier module 125 can carry the wafer W between the developing module 121 and the load lock module 110 and the like while holding the wafer W by the carrier arm 125a.

The relay carrier section 4 carries the wafer W between the wet treatment section 2 and the dry treatment section 3, specifically, carries the wafers W on a wafer-by-wafer basis, namely, in a single wafer manner.

In the relay carrier section 4, a carrier path 13 is provided, and the wafer W is carried between the wet treatment section 2 and the dry treatment section 3 via the carrier path 130. The carrier path 130 in the relay carrier section 4 constitutes a carrier route extending in the depth direction (X-direction in the drawing) including the delivery tower 50 and the like in the delivery block BL2.

In this embodiment, the relay carrier section 4 is connected to a portion of the wet treatment section 2 farther from the exposure apparatus E than the treatment block BL1, specifically, connected to the delivery block BL2. More specifically, the carrier path 130 in the relay carrier section 4 is connected to the delivery block BL2.

In the carrier path 130, a carrier module 131 for carrying the wafer W is arranged.

The carrier module 131 has a carrier arm 131a movable, for example, in the vertical direction and the direction around the vertical axis. The carrier module 131 can carry the wafer W between the plurality of delivery modules 53 in the delivery tower 52, and the load lock module 110 while holding the wafer W by the carrier arm 131a.

The above wafer treatment apparatus 1 is provided with at least one controller 5 as illustrated in FIG. 1. The controller 5 processes computer-executable instructions which cause the wafer treatment apparatus 1 to execute various processes described in this disclosure. The controller 5 can be configured to control components of the wafer treatment apparatus 1 to execute the various processes described herein. In one embodiment, a part or all of the controller 5 may be included in the wafer treatment apparatus 1. The controller 5 may include a processor, a storage, and a communication interface. The controller 5 is realized, for example, by a computer. The processor can be configured to read from the storage a program which provides a logic or routine for making it possible to perform various control operations, and execute the read program to thereby perform the various control operations. This program may be stored in the storage in advance, or acquired via a medium when necessary. The acquired program is stored in the storage, and read from the storage and executed by the processor. The medium may be computer-readable various storage media or may be a communication line connected to the communication interface. The storage medium may be a transitory medium or a non-transitory medium H. The processor may be a CPU (Central Processing Unit) or one or a plurality of circuits. The storage may include a RAM (Random Access Memory), a ROM (Read Only Memory), an HDD (Hart Disk Drive), an SSD (Solid State Drive), or a combination of them. The communication interface may communicate with the wafer treatment apparatus 1 via a communication line such as a LAN (Local Area Network).

### <Example 1 of a Treatment Sequence>

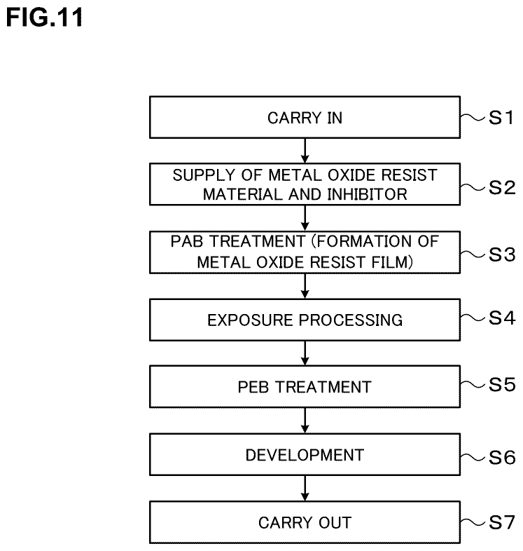

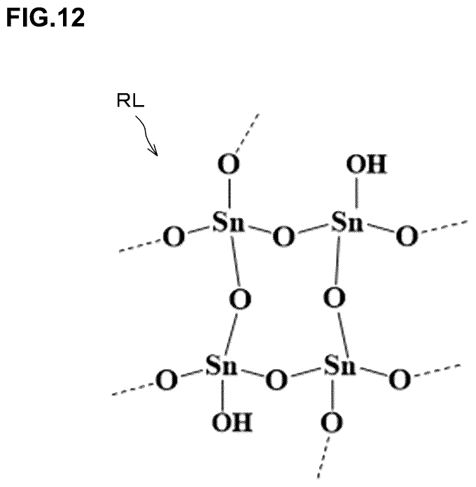

Next, an example of a treatment sequence executed by the wafer treatment apparatus 1 will be explained. FIG. 11 is a flowchart illustrating main processes in Example 1 of the treatment sequence. FIG. 12 is a chart for explaining the state of the exposed portion of the film of the metal oxide resist.

First, as illustrated in FIG. 11, the wafer W is carried into the wafer treatment apparatus 1 (Step S1).

Specifically, for example, the wafer W is first taken out by the carrier module 23 in the wet treatment section 2 from the cassette C on the cassette stage 20 and carried to the delivery module 51 in the delivery tower 50 in the delivery block BL2.

Note that Step S1 is an example of the process of preparing the wafer W.

Next, the metal oxide resist material and the inhibitor are supplied to the wafer W, specifically, the liquid of the metal oxide resist material and the liquid of the inhibitor are simultaneously supplied (Step S2).

Specifically, for example, the wafer W is carried by the carrier module R2 to the resist supply module 31 in the treatment block BL1. Then, the liquid of the metal oxide resist material and the liquid of the inhibitor are simultaneously supplied to the wafer W in the resist supply module 31. The supplied liquid of the metal oxide resist material and liquid of the inhibitor are diffused by the rotation of the wafer W over the entire wafer surface. This forms a liquid film of a mixture of the liquid of the metal oxide resist material and the liquid of the inhibitor in a manner to cover the surface of the wafer W.

Further, the simultaneous supply of the liquid of the metal oxide resist material and the liquid of the inhibitor is preferably performed under an atmosphere of an inert gas such as a nitrogen gas. This makes it possible to prevent reaction of the moisture in the atmosphere around the wafer W with the inhibitor.

Next, a pre-applied bake (PAB) treatment is performed on the wafer W (Step S3). This causes at least any one of a cluster and its precursor contained in the metal oxide resist material to react with the inhibitor. As a result, it is possible to form a film of the metal oxide resist containing the polymer in which metals in the metal oxide resist material are linked in a chain while preventing the cluster from remaining on the wafer W.

In the PAB treatment, specifically, the wafer W is carried to the thermal treatment module 40 for the PAB treatment, in which a heat treatment is performed on the wafer W.

Thereafter, the wafer W is carried to the delivery module 61 in the delivery tower 60 in the interface station 12.

The target temperature, namely, the set temperature of the wafer W during the PAB treatment at Step S3 is a temperature higher than room temperature and 250° C. or lower.

Note that depending on the types of the metal oxide resist material and the inhibitor, a cooling treatment may be performed on the wafer W in place of the PAB treatment, namely, the heat treatment. In this case, the target temperature, namely, the set temperature of the wafer W during the cooling treatment is a temperature lower than room temperature and 0° C. or higher.

Further, the treatment time of the PAB treatment or the cooling treatment at Step S3 is, for example, one minute to one day.

Subsequently, exposure processing is performed on the wafer W (Step S4).

Specifically, for example, the wafer W is carried by the carrier module R4 to the exposure apparatus E, in which pattern exposure processing with EUV light is performed on the wafer W. Thus, a predetermined pattern formed in the mask is transferred by EUV light to the film of the metal oxide resist containing the above polymer on the wafer W.

At the exposed portion in the film of the metal oxide resist, the organic ligand in the polymer is removed so that the polymer becomes an active state. When the polymer in the active state reacts with the moisture in the surrounding atmosphere, a hydroxyl group bonds with a portion where the ligand is removed, so that the polymer is hydrophilized. Then, the hydrophilized polymers aggregate, namely, dehydrate and condense with each other, whereby the exposed portion in the film of the metal oxide resist becomes insoluble to the developing material.

For example, in the case where the cluster of the metal oxide resist material has a three-dimensional network structure of tin (Sn) and oxygen (O) as illustrated in FIG. 4, the exposed portion in the film of the metal oxide resist, namely, an insoluble portion to the developing material comes to have a two-dimensional network structure of tin (Sn) and oxygen (O) as exemplified with a code RL in FIG. 12.

On the other hand, at the unexposed portion in the film of the metal oxide resist, the reaction as at the exposed portion occurs limitedly and, for example, most of the polymer remains as it is.

After the pattern exposure processing, the wafer W is carried by the carrier module R4 to the delivery module 61 in the delivery tower 60.

Next, a heat treatment (PEB treatment) after the exposure processing is performed on the wafer W (Step S5).

Specifically, for example, the wafer W is carried by the carrier module R2 to the thermal treatment module 40 for the PEB treatment, in which a heat treatment using the hot plate 41 is performed on the wafer W. This promotes the above hydrophilization and dehydration-condensation to promote the insolubilization of the exposed portion in the film of the metal oxide resist to a polar developing material.

The target temperature, namely, the set temperature of the wafer W during the PEB treatment at Step S5 is a temperature higher than room temperature and 250° C. or lower as in the PAB treatment.

Note that depending on the types of the metal oxide resist material and the inhibitor, a cooling treatment may be performed on the wafer W in place of the PEB treatment, namely, the heat treatment. In this case, the target temperature, namely, the set temperature of the wafer W during the cooling treatment is a temperature lower than room temperature and 0° C. or higher.

Further, the treatment time of the PEB treatment or the cooling treatment at Step S5 is, for example, one minute to one day.

Subsequently, the wafer W is developed (Step S6).

Specifically, for example, the wafer W is carried by the carrier module R2 to the developing module 30. In the developing module 30, a liquid film of a nonpolar developing solution as the developing material is formed on the wafer W, so that the unexposed portion in the film of the metal oxide resist is selectively removed with the developing solution.

By Step S6, a pattern of the metal oxide resist is formed.

Then, the wafer W is carried out of the wafer treatment apparatus 1 (Step S7).

Specifically, the wafer W is returned to the cassette C in a procedure reverse to that at Step S1.

This completes the series of treatment sequence.

### <Main Effects of Example 1 of the Treatment Sequence>

In Example 1 of the treatment sequence, not only the above metal oxide resist material containing at least one of the cluster and its precursor but also the inhibitor are supplied to the wafer W.

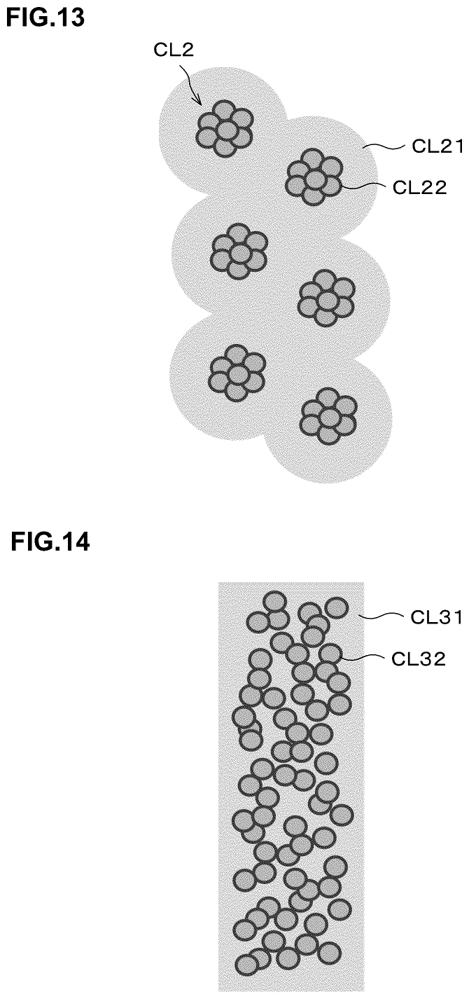

In a form in which the inhibitor is not supplied but only the metal oxide resist material is supplied (hereinafter, referred to as a “comparison form”), the cluster remains at the unexposed portion in the resist film after the PEB treatment. Specifically, as illustrated in FIG. 13, a cluster CL2 around which an organic ligand CL21 is arranged exists at a cycle of 1 to 2 nm at the unexposed portion, namely, sparseness and denseness in presence of a metal CL22 constituting the metal oxide resist exists at the unexposed portion. The calculated dimension of the cluster CL2 including the organic ligand CL21 is 1.1 nm×1.4 nm in the case where the metal constituting the cluster CL2 is tin. This cluster exists also at the boundary between the unexposed portion and the exposed portion. Therefore, when a resist pattern is formed by removing the unexposed portion, irregularities are generated at a position corresponding to the cluster on the surface of the resist pattern, causing deterioration in roughness (specifically, LER (Line Edge Roughness)) on the surface.

In contrast to this, the inhibitor is also supplied to the wafer W in this example, thus preventing the cluster from remaining at the unexposed portion in the film of the metal oxide after the PEB treatment. Therefore, as illustrated in FIG. 14, a metal CL32 around which an organic ligand CL31 is arranged constituting the metal oxide resist exists at the unexposed portion more uniformly than in the comparison form. In other words, the chemical stochastics at the unexposed portion is improved as compared with the comparison form. Accordingly, when the pattern of the metal oxide resist is formed by removing the unexposed portion, it is possible to prevent relatively large irregularities due to the cluster from being generated on the surface of the pattern. Therefore, according to this example, it is possible to improve the roughness (specifically, LER) on the surface of the pattern of the metal oxide resist.

### <Example 2 of the Treatment Sequence>

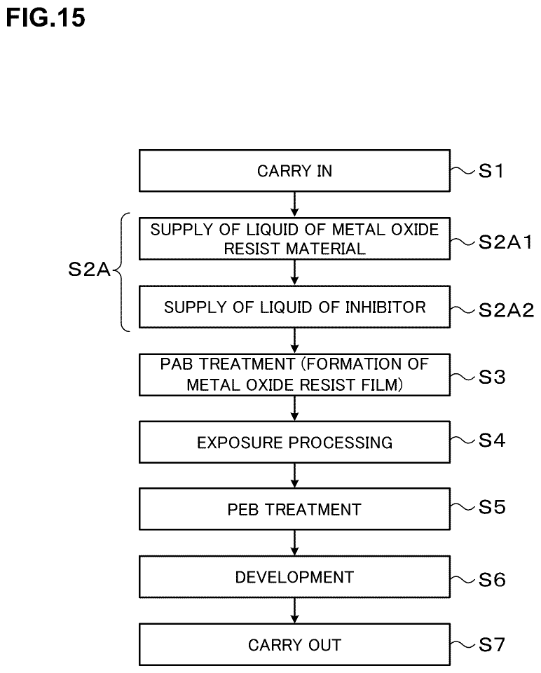

FIG. 15 is a flowchart illustrating main processes in Example 2 of the treatment sequence.

In above Example 1 of the treatment sequence, when the metal oxide resist material and the inhibitor are supplied, the liquid of the metal oxide resist material and the liquid of the inhibitor are simultaneously supplied. In contrast to that, in this example, at Step S2A where the metal oxide resist material and the inhibitor are supplied, their liquids are supplied as in above Example 1 but the supply timings of the liquids are different from each other unlike above Example 1, as illustrated in FIG. 15.

Specifically, at Step S2A in this example, first, the liquid of the metal oxide resist material is supplied to the wafer W (Step S2A1).

More specifically, for example, the wafer W is carried by the carrier module R2 to the resist supply module 31 in the treatment block BL1. Then, the liquid of the metal oxide resist material is supplied to the wafer W in the resist supply module 31. The supplied liquid of the metal oxide resist material is diffused by the rotation of the wafer W over the entire wafer surface. This forms a liquid film of the liquid of the metal oxide resist material in a manner to cover the surface of the wafer W.

Subsequently, the liquid of the inhibitor is supplied to the wafer W (Step S2A2).

Specifically, the liquid of the inhibitor is supplied to the wafer W in the resist supply module 31. The supplied liquid of the inhibitor is diffused by the rotation of the wafer W over the entire wafer surface. This forms a liquid film of a mixture of the liquid of the metal oxide resist material and the liquid of the inhibitor in a manner to cover the surface of the wafer W. The supply of the liquid of the inhibitor at Step S2A2 is preferably performed under an atmosphere of an inert gas such as a nitrogen gas. This makes it possible to prevent reaction of the moisture in the atmosphere around the wafer W with the inhibitor.

The steps other than Step S2A in this example are the same as those in above Example 1.

### <Modification of Example 2 of the Treatment Sequence>

In above Example 2 of the treatment sequence, the supply of the liquid of the metal oxide resist material (Step S2A1) is performed and then the supply of the liquid of the inhibitor (Step S2A2) is performed on the wafer W. Instead of this, the supply of the metal oxide resist material (Step S2A1) may be performed after the supply of the liquid of the inhibitor (Step S2A2) is performed on the wafer W. This can also form the liquid film of the mixture of the liquid of the metal oxide resist material and the liquid of the inhibitor.

### <Example 3 of the Treatment Sequence>

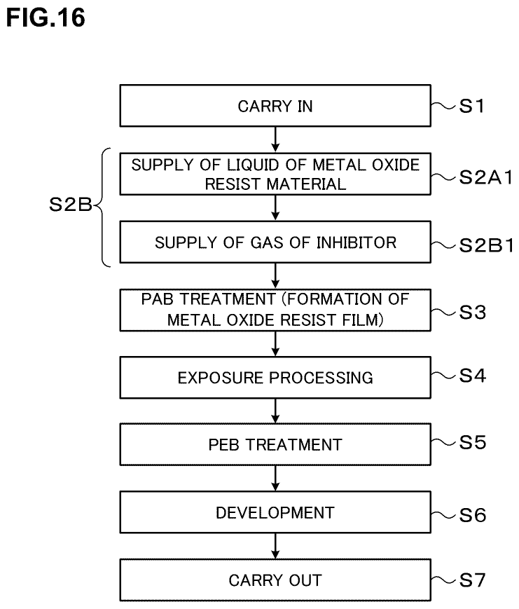

FIG. 16 is a flowchart illustrating main processes in Example 3 of the treatment sequence.

In this example, at Step S2B where the metal oxide resist material and the inhibitor are supplied, the supply of the inhibitor is performed after the supply of the liquid of the metal oxide resist material is performed (Step S2A1) on the wafer W as at Step S2A in above Example 2 of the treatment sequence. However, in this example, gas of the inhibitor is supplied to the wafer W (Step S2B1) unlike above Example 2.

At Step S2B1, specifically, the gas of the inhibitor is supplied to the wafer W in the resist supply module 31. Thus, the inhibitor is taken into the liquid film composed of the liquid of the metal oxide resist material formed at Step S2A1. The supply of the gas of the inhibitor at Step S2B1 is preferably performed under an atmosphere of an inert gas such as a nitrogen gas. This makes it possible to prevent reaction of the moisture in the atmosphere around the wafer W with the inhibitor.

According to this example, it is possible to prevent the liquid of the metal oxide resist material from being drained from the top of the wafer W during at the supply of the inhibitor.

### <Configuration Example of the Resist Supply Module 31 Applicable to Example 1 of the Treatment Sequence>

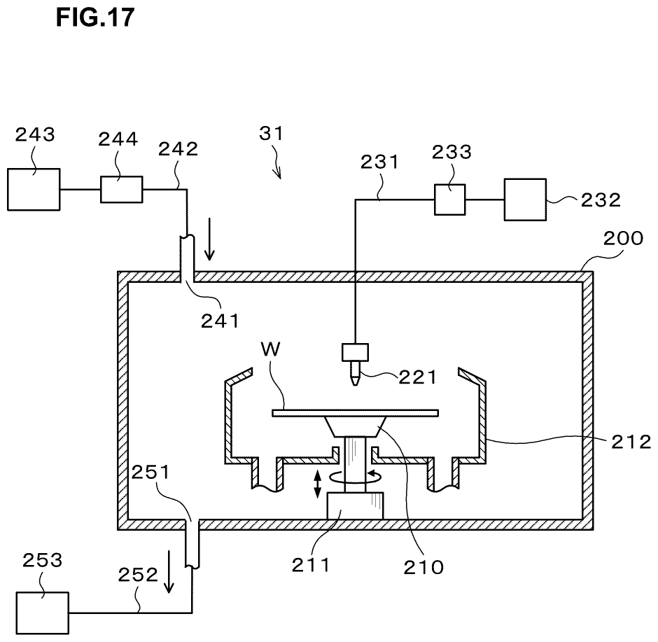

FIG. 17 is a view illustrating a configuration example of the resist supply module 31 applicable to Example 1 of the treatment sequence.

The resist supply module 31 in FIG. 17 has a treatment chamber 200 whose inside is sealable. At one side surface of the treatment chamber 200, a carry-in/out port (not illustrated) for the wafer W is formed, and an opening and closing shutter (not illustrated) is provided at the carry-in/out port. At a central portion in the treatment chamber 200, a spin chuck 210 which holds and rotates the wafer W is provided. The spin chuck 210 has a horizontal upper surface, and the upper surface is provided with, for example, a suction port (not illustrated) for sucking the wafer W. By the suction through the suction port, the wafer W can be suction-held on the spin chuck 210.

Below the spin chuck 210, a chuck drive 211 including, for example, a motor and the like is provided. The spin chuck 210 can be rotated at a predetermined speed by the chuck drive 211. Further, the chuck drive 211 is provided with, for example, a raising and lowering drive source such as a cylinder so that the spin chuck 210 freely rises and lowers.

Around the spin chuck 210, a cup 212 is provided which receives and collects liquid splashing or dropping from the wafer W.

Further, in the treatment chamber 200, a discharge nozzle 221 is provided which discharges a mixed solution of the liquid of the metal oxide resist material and the liquid of the inhibitor to the wafer W held on the spin chuck 210. The discharge nozzle 221 is configured to be movable in a radial direction of the wafer W held on the spin chuck 210 in plan view and to be able to rise and lower.

To the discharge nozzle 221, a supply pipe 231 is connected which supplies the mixed solution to the discharge nozzle 221. The supply pipe 231 communicates with a supply source 232 which stores the mixed solution therein. Further, the supply pipe 231 is provided with a supply equipment group 233 including a valve, a flow control valve, and so on for controlling the flow of the mixed solution.

Further, the treatment chamber 200 is provided with a discharge port 241 which discharges an inert gas such as a nitrogen gas into the treatment chamber 200. To the discharge port 241, a supply pipe 242 is connected which supplies the inert gas to the discharge port 241. The supply pipe 242 communicates with a supply source 243 of the inert gas. Further, the supply pipe 242 is provided with a supply equipment group 244 including a valve, a flow control valve, and so on for controlling the flow of the inert gas.

In other words, the treatment chamber 200 is configured to allow the inside thereof to be brought into an inert gas atmosphere.

Further, the treatment chamber 200 is formed with an exhaust port 251 which exhausts gas from the inside of the treatment chamber 200. To the exhaust port 251, for example, an exhaust pipe 252 is connected which communicates with an exhaust mechanism 253 having a vacuum pump and the like.

In the resist supply module 31 in FIG. 17, the mixed solution of the liquid of the metal oxide resist material and the liquid of the inhibitor can be supplied via the discharge nozzle 221 to the wafer W held on the spin chuck 210.

Further, in the resist supply module 31 in FIG. 17, the mixed solution of the liquid of the metal oxide resist material and the liquid of the inhibitor can be supplied via the discharge nozzle 221 to the wafer W housed inside the treatment chamber 200 with the inert gas atmosphere and held on the spin chuck 210.

Specifically, in the resist supply module 31 in FIG. 17, the mixed solution can be supplied via the discharge nozzle 221 to the wafer W housed inside the treatment chamber 200 with the inert gas atmosphere and at a pressure higher than the atmospheric pressure and held on the spin chuck 210.

### <Configuration Example of the Resist Supply Module 31 Applicable to Examples 1, 2 of the Treatment Sequence and a Modification of Example 2>

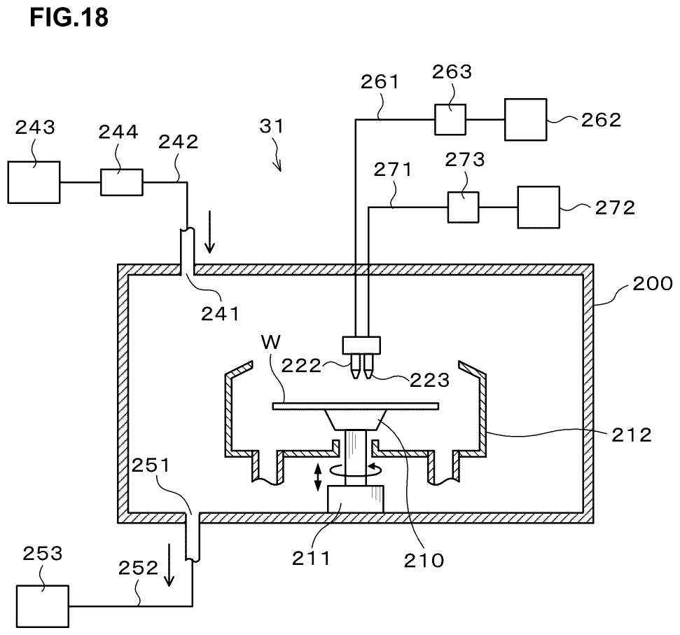

FIG. 18 is a view illustrating a configuration example of a resist supply module 31 applicable to Examples 1, 2 of the treatment sequence and a modification of Example 2.

In the resist supply module 31 in FIG. 18, discharge nozzles 222, 223 are provided in place of the discharge nozzle 221 which discharges the mixed solution of the liquid of the metal oxide resist material and the liquid of the inhibitor, in the treatment chamber 200.

The discharge nozzle 222 discharges the liquid of the metal oxide resist material to the wafer W held on the spin chuck 210. On the other hand, the discharge nozzle 223 discharges the liquid of the inhibitor to the wafer W held on the spin chuck 210. The discharge nozzles 222, 223 are configured to be movable in a radial direction of the wafer W held on the spin chuck 210 in plan view and to be able to rise and lower.

To the discharge nozzle 222, a supply pipe 261 is connected which supplies the liquid of the metal oxide resist material to the discharge nozzle 222. The supply pipe 261 communicates with a supply source 262 for storing the liquid of the metal oxide resist material therein. Further, the supply pipe 261 is provided with a supply equipment group 263 including a valve, a flow control valve, and so on for controlling the flow of the liquid of the metal oxide resist material.

To the discharge nozzle 223, a supply pipe 271 is connected which supplies the liquid of the inhibitor to the discharge nozzle 223. The supply pipe 271 communicates with a supply source 272 for storing the liquid of the inhibitor therein. Further, the supply pipe 271 is provided with a supply equipment group 273 including a valve, a flow control valve, and so on for controlling the flow of the liquid of the inhibitor.

In the resist supply module 31 in FIG. 18, the liquid of the metal oxide resist material can be supplied via the discharge nozzle 222 and the liquid of the inhibitor can be supplied via the discharge nozzle 223, to the wafer W held on the spin chuck 210.

Further, in the resist supply module 31 in FIG. 18, the liquid of the inhibitor can be supplied via the discharge nozzle 221 to the wafer W housed inside the treatment chamber 200 with the inert gas atmosphere and held on the spin chuck 210.

Specifically, in the resist supply module 31 in FIG. 18, the liquid of the inhibitor can be supplied via the discharge nozzle 221 to the wafer W housed inside the treatment chamber 200 with the inert gas atmosphere and at a pressure higher than the atmospheric pressure and held on the spin chuck 210.

Note that in the resist supply module 31 in this example, it is preferable to use a nonpolar one (for example, hexane) for the solvent contained in the liquid of the inhibitor. This makes it possible to prevent the metal oxide resist material from dissolving in the solvent in the liquid of the inhibitor.

### <Other Configuration Examples of the Resist Supply Module 31 Applicable to Example 1 of the Treatment Sequence>

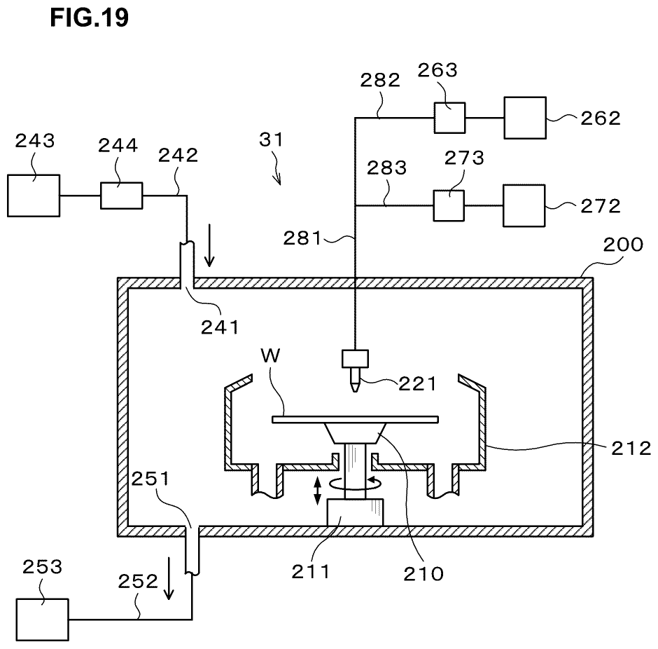

FIG. 19 is a view illustrating another configuration example of the resist supply module 31 when Example 1 of the treatment sequence is applied.

In the resist supply module 31 in FIG. 19, a discharge nozzle 221 is provided in the treatment chamber 200, which discharges a mixed solution of the liquid of the metal oxide resist material and the liquid of the inhibitor to the wafer W held on the spin chuck 210, as in the one in FIG. 17. However, the upstream side of a supply pipe 281 for supplying the mixed solution to the discharge nozzle 221 is branched into two branch pipes 283, 283. One branch pipe 282 communicates with the supply source 262 for storing the liquid of the metal oxide resist material therein, and the other branch pipe 283 communicates with the supply source 272 for storing the liquid of the inhibitor therein. Further, the supply pipe 282 is provided with a supply equipment group 263 including a valve, a flow control valve, and so on for controlling the flow of the liquid of the metal oxide resist material, and the supply pipe 283 is provided with a supply equipment group 273 including a valve, a flow control valve, and so on for controlling the flow of the liquid of the inhibitor.

Also in the resist supply module 31 in this example, the mixed solution of the liquid of the metal oxide resist material and the liquid of the inhibitor can be supplied via the discharge nozzle 221 to the wafer W held on the spin chuck 210.

Further, also in the resist supply module 31 in this example, the mixed solution of the liquid of the metal oxide resist material and the liquid of the inhibitor can be supplied via the discharge nozzle 221 to the wafer W housed inside the treatment chamber 200 with the inert gas atmosphere and held on the spin chuck 210.

Specifically, in also the resist supply module 31 in this example, the mixed solution can be supplied via the discharge nozzle 221 to the wafer W housed inside the treatment chamber 200 with the inert gas atmosphere and at a pressure higher than the atmospheric pressure and held on the spin chuck 210.

### <Configuration Example of the Resist Supply Module 31 Applicable to Example 3 of the Treatment Sequence>

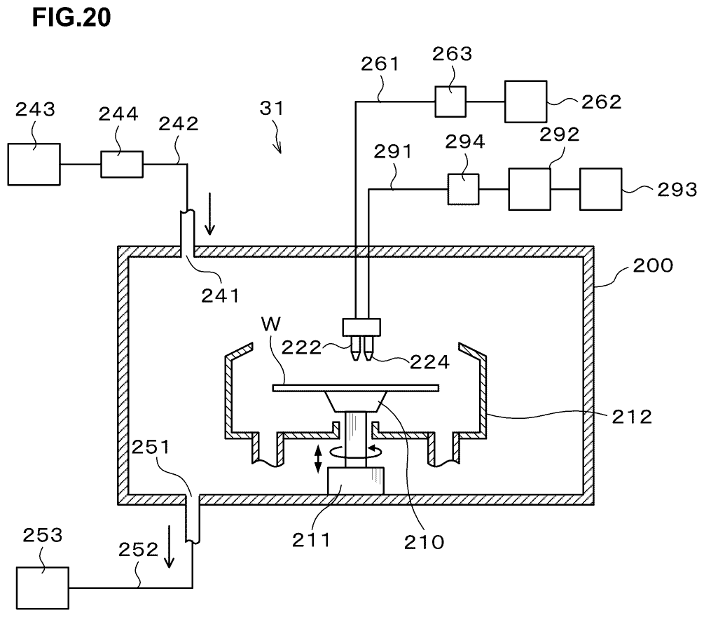

FIG. 20 is a view illustrating a configuration example of the resist supply module 31 applicable to Example 3 of the treatment sequence.

In the resist supply module 31 in FIG. 20, a discharge nozzle 224 is provided in addition to the above discharge nozzle 222 in the treatment chamber 200.

The discharge nozzle 224 discharges gas of the inhibitor to the wafer W held on the spin chuck 210. The gas of the inhibitor may be discharged from a shower head (not illustrated) formed with a plurality of discharge holes in a surface facing the wafer W held on the spin chuck 210 in place of the discharge nozzle 224.

To the discharge nozzle 224, a supply pipe 291 is connected which supplies the gas of the inhibitor to the discharge nozzle 224. The supply pipe 291 communicates with a vaporizer 292. The vaporizer 292 vaporizes the liquid of the inhibitor supplied from a supply source 293 for storing the liquid of the inhibitor therein to produce the gas of the inhibitor. Further, the supply pipe 291 is provided with a supply equipment group 294 including a valve, a flow control valve, and so on for controlling the flow of the liquid of the inhibitor from the vaporizer 292.

In the resist supply module 31 in FIG. 20, the gas of the inhibitor can be supplied via the discharge nozzle 224 to the wafer W held on the spin chuck 210.

Further, in the resist supply module 31 in FIG. 20, the gas of the inhibitor can be supplied via the discharge nozzle 224 to the wafer W housed inside the treatment chamber 200 with the inert gas atmosphere and held on the spin chuck 210.

Specifically, in the resist supply module 31 in FIG. 20, the gas of the inhibitor can be supplied via the discharge nozzle 224 to the wafer W housed inside the treatment chamber 200 with the inert gas atmosphere and at a pressure higher than the atmospheric pressure and held on the spin chuck 210.

### <Example 4 of the Treatment Sequence>

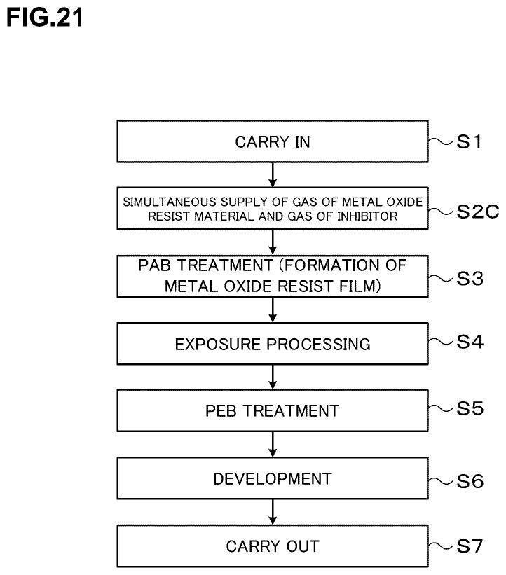

FIG. 21 is a flowchart illustrating main processes in Example 4 of the treatment sequence.

In above Example 1 of the treatment sequence, when the metal oxide resist material and the inhibitor are supplied, the liquid of the metal oxide resist material and the liquid of the inhibitor are simultaneously supplied. In contrast to that, in this example, as illustrated in FIG. 21, at Step S2C where the metal oxide resist material and the inhibitor are supplied, gas of the metal oxide resist material and gas of the inhibitor are simultaneously supplied. In other words, the gas of the metal oxide resist material and the gas of the inhibitor are simultaneously supplied to the wafer W in a dry manner. Thus, a film in which the metal oxide resist material and the inhibitor are mixed is formed on the wafer W.

The simultaneous supply of the gas of the metal oxide resist material and the gas of the inhibitor may be performed under a reduced-pressure atmosphere, under an atmosphere of an inert gas, or under a reduced-pressure atmosphere and under an atmosphere of an inert gas. This makes it possible to prevent reaction of the moisture in the atmosphere around the wafer W with the inhibitor.

The steps other than Step S2C in this example are the same as those in above Example 1.

### <Example 5 of the Treatment Sequence>

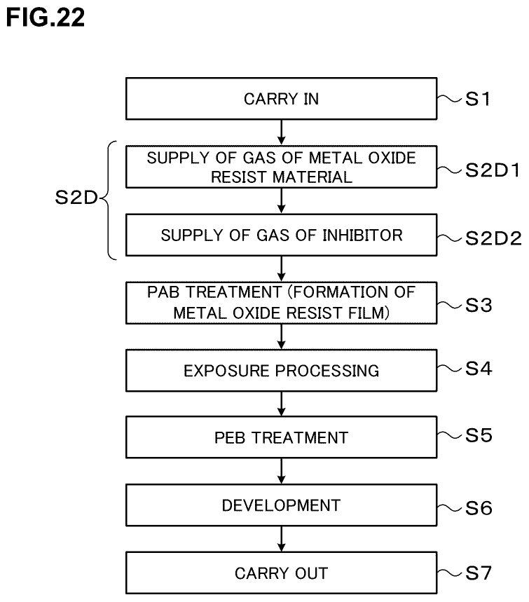

FIG. 22 is a flowchart illustrating main processes in Example 5 of the treatment sequence.

In above Example 4 of the treatment sequence, the gas of the metal oxide resist material and the gas of the inhibitor are simultaneously supplied. In contrast to that, in this example, as illustrated in FIG. 22, at Step S2D where the metal oxide resist material and the inhibitor are supplied, the supply timings of the gas of the metal oxide resist material and the gas of the inhibitor are different from each other unlike above Example 4.

Specifically, at Step S2D in this example, the gas of the metal oxide resist material is first supplied to the wafer W (Step S2D1). Thus, a film of the metal oxide resist material is formed on the wafer W.

Subsequently, the gas of the inhibitor is supplied to the wafer W (Step S2D2)

Thus, a film of the inhibitor is layered on the film of the metal oxide resist material.

For example, by the PAB treatment thereafter, the metal oxide resist material and the inhibitor move on the wafer W, whereby a film in which the metal oxide resist material and the inhibitor are mixed is formed on the wafer W.

Note that the gas of the metal oxide resist material is, for example, the one made by vaporizing the liquid of the metal oxide resist material exemplified above. Besides, the gas of the inhibitor is, for example, the one made by vaporizing the liquid of the inhibitor exemplified above.

The supply of the gas of the inhibitor at Step S2D2 may be performed under a reduced-pressure atmosphere, under an atmosphere of an inert gas, or under a reduced-pressure atmosphere and under an atmosphere of an inert gas. This makes it possible to prevent reaction of the moisture in the atmosphere around the wafer W with the inhibitor.

Further, also the supply of the gas of the metal oxide resist material at Step S2D1 may be performed under a reduced-pressure atmosphere, under an atmosphere of an inert gas, or under a reduced-pressure atmosphere and under an atmosphere of an inert gas.

The steps other than Step S2D in this example are the same as those in above Example 1.

### <Modifications of Examples 4, 5 of the Treatment Sequence>

During the supply of the gas of the metal oxide resist material and the gas of the inhibitor at Step S2C and Step S2D, the wafer W may be heated. In this case, the PAB treatment may be omitted.

### <Another Modification of Example 5 of the Treatment Sequence>

In above Example 5 of the treatment sequence, the supply of the gas of the inhibitor (Step S2D2) is performed after the supply of the gas of the metal oxide resist material (Step S2D1) is performed on the wafer W. Instead of this, the supply of the gas of the metal oxide resist material (Step S2D1) may be performed after the supply of the inhibitor (Step S2D2) is performed on the wafer W. Also in this case, for example, a film in which the metal oxide resist material and the inhibitor are mixed is formed on the wafer W by the PAB treatment thereafter.

Note that in the case of Examples 4, 5 of the treatment sequence and a modification of Example 5, only the precursor of the above cluster and its precursor is contained in the metal oxide resist material.

### <Configuration Example of the Resist Supply Module Applicable to Examples 4, 5 of the Treatment Sequence and Modifications Thereof>

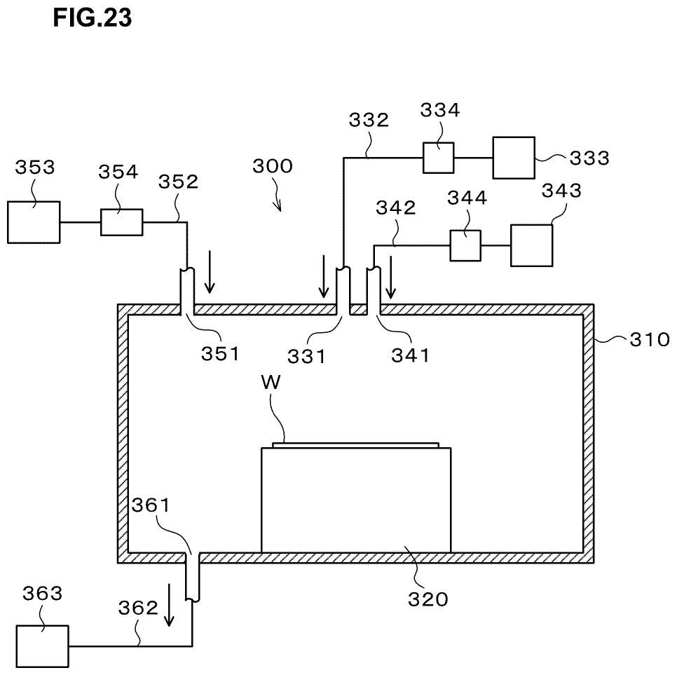

FIG. 23 is a view illustrating a configuration example of the resist supply module applicable to Examples 4, 5 of the treatment sequence and modifications thereof.

A resist supply module 300 in FIG. 23 has a treatment chamber 310 whose inside is sealable. At one side surface of the treatment chamber 310, a carry-in/out port (not illustrated) for the wafer W is formed, and an opening and closing shutter (not illustrated) is provided at the carry-in/out port.

In the treatment chamber 310, a stage 320 on which the wafer W is mounted is provided. The stage 320 has a horizontal upper surface, and the wafer W is held on the upper surface by electrostatic attraction or the like. Further, the stage 320 may be provided with a heating mechanism which heats the wafer W mounted on the stage 320.

Further, the treatment chamber 310 is provide with discharge ports 331, 341, 351.

The discharge port 331 discharges the gas of the metal oxide resist material to the inside of the treatment chamber 310. To the discharge port 331, a supply pipe 332 is connected which supplies the gas of the metal oxide resist material to the discharge port 331. The supply pipe 332 communicates with a supply source 333 for the gas of the metal oxide resist material. Further, the supply pipe 332 is provided with a supply equipment group 334 including a valve, a flow control valve, and so on for controlling the flow of the gas of the metal oxide resist material.

The discharge port 341 discharges the gas of the inhibitor to the inside of the treatment chamber 310. To the discharge port 341, a supply pipe 342 is connected which supplies the gas of the inhibitor to the discharge port 341. The supply pipe 342 communicates with a supply source 343 for the gas of the inhibitor. Further, the supply pipe 342 is provided with a supply equipment group 344 including a valve, a flow control valve, and so on for controlling the flow of the gas of the inhibitor.

The discharge port 351 discharges the inert gas to the inside of the treatment chamber 310. To the discharge port 351, a supply pipe 352 is connected which supplies the inert gas to the discharge port 351. The supply pipe 352 communicates with a supply source 353 for the inert gas. Further, the supply pipe 352 is provided with a supply equipment group 354 including a valve, a flow control valve, and so on for controlling the flow of the inert gas.

Further, the treatment chamber 310 is formed with an exhaust port 361 which exhausts gas from the inside of the treatment chamber 310. To the exhaust port 361, for example, an exhaust pipe 362 is connected which communicates with an exhaust mechanism 363 having, for example, a vacuum pump or the like.

In the resist supply module 300 in this example, the gas of the metal oxide resist can be supplied via the discharge port 331 to the wafer W housed inside the treatment chamber 310 and held on the stage 320.

Further, in the resist supply module 300 in this example, the gas of the metal oxide resist material can be supplied via the discharge port 331 to the wafer W housed inside the treatment chamber 310 with the reduced-pressure atmosphere and held on the stage 320.

Further, in the resist supply module 300 in this example, the gas of the metal oxide resist material can be supplied via the discharge port 331 to the wafer W housed inside the treatment chamber 310 with the reduced-pressure atmosphere and the inert gas atmosphere and held on the stage 320.

In the resist supply module 300 in this example, the gas of the inhibitor can be supplied via the discharge port 341 to the wafer W housed inside the treatment chamber 310 and held on the stage 320.

Further, in the resist supply module 300 in this example, the gas of the inhibitor can be supplied via the discharge port 341 to the wafer W housed inside the treatment chamber 310 with the reduced-pressure atmosphere and held on the stage 320.

Further, in the resist supply module 300 in this example, the gas of the inhibitor can be supplied via the discharge port 331 to the wafer W housed inside the treatment chamber 310 with the reduced-pressure atmosphere and the inert gas atmosphere and held on the stage 320.

The above resist supply module 300 is provided, for example, in place of some of the plurality of developing modules 121 in the dry treatment section 3.

Further, when the inside of the treatment chamber 310 does not need to be brought into the reduced-pressure atmosphere, for example, the exhaust port 361, the exhaust pipe 362, and the exhaust mechanism 363 are omitted, and the resist supply module 300 is provided in place of some of the plurality of thermal treatment modules 40 in the wet treatment section 2.

### <Other Modifications of Examples 1 to 5 of the Treatment Sequence>

A post-bake treatment is not performed on the wafer W in above Examples 1 to 5 of the treatment sequence and modifications thereof, but may be performed. The post-bake treatment is performed by the thermal treatment module 40 for that treatment.

Besides, the wet development is performed as the development in Examples 1 to 5 of the treatment sequence and modifications thereof, but dry development may be performed under a reduced-pressure atmosphere in place of the wet development. In the case where the dry development is performed, the developing module 121 in the dry treatment section 3 is used.

Further, in place of the wet development and the dry development, development using gas of acetic acid may be performed under an atmosphere at the atmospheric pressure or higher. The development using the gas of acetic acid is performed, for example, together with heating of the wafer W. A developing module for the development using the gas of acetic acid is provided to be stacked on the thermal treatment module 40, for example, in the wet treatment section 2.

Further, in order to enhance the solubility of the unexposed portion of the film of the metal oxide resist with respect to the developing material, one-shot exposure of the entire surface of the wafer W using ultraviolet light, namely, ultraviolet irradiation processing may be performed between the exposure processing of transferring the pattern and the PEB treatment or between the PEB treatment and the development. The one-shot exposure is performed, for example, by the ultraviolet irradiation module 45. In the case of performing the ultraviolet irradiation processing, a tetraethylammonium hydroxide aqueous solution may be used as the developing solution during the developing treatment thereafter. This is because an unexposed portion to EUV light in the film of the metal oxide resist becomes a hydroxide such as a tin hydroxide by the ultraviolet irradiation processing and comes to be soluble in the aqueous solution.

### <Other Examples of the Inhibitor>

In the above example, tin (atom) in the tin compound contained in the inhibitor is bonded to the oxygen (O) atom in a portion other than the organic group. In place of or in addition to this, in the tin compound contained in the inhibitor, tin (atom) in the compound may have a nitrogen (N) atom or halogen bonded to a portion other than an organic group CC.

### <Modification of the Wafer Treatment Apparatus 1>

The components of the wafer treatment apparatus 1 may be appropriately omitted according to the treatment sequence performed by the wafer treatment apparatus 1. In other words, in the case where the wafer treatment apparatus 1 performs only part of the examples of the treatment sequence, the components of the wafer treatment apparatus 1 which are not used in the treatment sequence to be performed may be omitted.

The embodiments disclosed herein are examples in all respects and should not be considered to be restrictive. Various omissions, substitutions, and changes may be made in the embodiments without departing from the scope and the spirit of the attached claims. For example, configuration requirements of the above embodiments can be arbitrarily combined. From the arbitrary combination, the operations and effects about the configuration requirements relating to the combination can be obtained as a matter of course, and other operations and other effects apparent to those skilled in the art are obtained from the description herein.

Besides, the effects explained herein are merely explanatory or illustrative in all respects and not restrictive. In other words, the technique relating to this disclosure can offer other effects apparent to those skilled in the art from the description herein in addition to or in place of the above effects.

Note that the following configuration examples also belong to the technical scope of this disclosure.

(1) A substrate treatment method including:
(A) preparing a substrate;
(B) supplying a metal oxide resist material containing at least any one of a cluster in which metals are three-dimensionally bonded and a precursor of the cluster and an inhibitor containing metal, to the substrate; and
(C) causing the at least any one of the cluster and the precursor to react with the inhibitor to form a resist film containing a polymer in which metals in the metal oxide resist material are linked in a chain.

(2) The substrate treatment method according to the (1), wherein:
the at least any one of the cluster and the precursor of the cluster has a structure in which one carbon is directly bonded to the metal; and
the inhibitor contains a compound having a structure in which two or more carbons are directly bonded to the metal.

(3) The substrate treatment method according to the (1) or (2), wherein
the (B) supplies liquid of the metal oxide resist material and liquid of the inhibitor to the substrate.

(4) The substrate treatment method according to the (3), wherein
the (B) supplies the liquid of the inhibitor to the substrate under an inert gas atmosphere.

(5) The substrate treatment method according to the (1) or (2), wherein
the (B) supplies gas of the inhibitor to the substrate after supplying liquid of the metal oxide resist material to the substrate.

(6) The substrate treatment method according to the (5), wherein
the (B) supplies the gas of the inhibitor to the substrate under an inert gas atmosphere.

(7) The substrate treatment method according to the (1) or (2), wherein
the (B) supplies gas of the metal oxide resist material and gas of the inhibitor to the substrate.

(8) The substrate treatment method according to the (7), wherein
the (B) supplies the gas of the inhibitor to the substrate under a nitrogen atmosphere.

(9) The substrate treatment method according to any one of the (1) to (8), further including
(D) developing the substrate on which the resist film has been formed and which has been subjected to exposure processing and a heat treatment after the exposure processing, with a halogen gas or gas of an acetic acid.

(10) The substrate treatment method according to any one of the (1) to (9), further including
(E) developing the substrate on which the resist film has been formed and which has been subjected to exposure processing a heat treatment after the exposure processing and ultraviolet irradiation processing, with a tetraethylammonium hydroxide aqueous solution.

(11) A substrate treatment apparatus, including:
a first supplier configured to supply a metal oxide resist material containing at least any one of a cluster in which metals are three-dimensionally bonded and a precursor of the cluster, to a substrate;
a second supplier configured to supply an inhibitor containing metal to the substrate; and
a reactor configured to cause the at least any one of the cluster and the precursor to react with the inhibitor to form a resist film containing a polymer in which metals in the metal oxide resist material are linked in a chain.

(12) The substrate treatment apparatus according to the (11), wherein:
the at least any one of the cluster and the precursor of the cluster has a structure in which one carbon is directly bonded to the metal; and
the inhibitor contains a compound having a structure in which two or more carbons are directly bonded to the metal.

(13) The substrate treatment apparatus according to the (11) or (12), wherein:
the first supplier supplies liquid of the metal oxide resist material to the substrate; and
the second supplier supplies liquid of the inhibitor to the substrate.

(14) The substrate treatment apparatus according to the (13), wherein
the second supplier
has a treatment chamber configured to allow an inside thereof to be brought into an inert gas atmosphere, and
supplies liquid of the inhibitor to the substrate housed inside the treatment chamber with the inert gas atmosphere.

(15) The substrate treatment apparatus according to the (11) or (12), wherein:
the first supplier supplies liquid of the metal oxide resist material to the substrate; and
the second supplier supplies gas of the inhibitor to the substrate after the first supplier supplies the liquid of the metal oxide resist material to the substrate.

(16) The substrate treatment apparatus according to the (15), wherein
the second supplier
has a treatment chamber configured to allow an inside thereof to be brought into an inert gas atmosphere, and
supplies the gas of the inhibitor to the substrate housed inside the treatment chamber with the inert gas atmosphere.

(17) The substrate treatment apparatus according to the (11) or (12), wherein:
each of the first supplier and the second supplier has a treatment chamber;
the first supplier supplies gas of the metal oxide resist material to the substrate housed inside the treatment chamber; and
the second supplier supplies gas of the inhibitor to the substrate housed inside the treatment chamber.

(18) The substrate treatment apparatus according to the (17) wherein:
the treatment chamber of the second supplier is configured to allow an inside thereof to be brought into an inert gas atmosphere; and
the second supplier supplies the gas of the inhibitor to the substrate housed inside the treatment chamber with the inert gas atmosphere.

(19) The substrate treatment apparatus according to the (11) or (12), further including
a developer configured to develop the substrate on which the resist film has been formed and which has been subjected to exposure processing and a heat treatment after the exposure processing, with gas containing halogen or gas of an acetic acid.

(20) The substrate treatment apparatus according to the (11) or (12), further including
a developer configured to develop the substrate on which the resist film has been formed and which has been subjected to exposure processing, a heat treatment after the exposure processing and ultraviolet irradiation processing, with a tetraethylammonium hydroxide aqueous solution.

According to this disclosure, it is possible to improve the roughness of a surface of a pattern of a metal oxide resist.

What is claimed is:

1. A substrate treatment method comprising:
(A) preparing a substrate;
(B) supplying a metal oxide resist material containing at least any one of a cluster in which metals are three-dimensionally bonded and a precursor of the cluster and an inhibitor containing metal, to the substrate; and
(C) causing the at least any one of the cluster and the precursor to react with the inhibitor to form a resist film containing a polymer in which metals in the metal oxide resist material are linked in a chain.

2. The substrate treatment method according to claim 1, wherein:
the at least any one of the cluster and the precursor of the cluster has a structure in which one carbon is directly bonded to the metal; and
the inhibitor contains a compound having a structure in which two or more carbons are directly bonded to the metal.

3. The substrate treatment method according to claim 1, wherein
the (B) supplies liquid of the metal oxide resist material and liquid of the inhibitor to the substrate.

4. The substrate treatment method according to claim 3, wherein
the (B) supplies the liquid of the inhibitor to the substrate under an inert gas atmosphere.

5. The substrate treatment method according to claim 1, wherein
the (B) supplies gas of the inhibitor to the substrate after supplying liquid of the metal oxide resist material to the substrate.

6. The substrate treatment method according to claim 5, wherein
the (B) supplies the gas of the inhibitor to the substrate under an inert gas atmosphere.

7. The substrate treatment method according to claim 1, wherein
the (B) supplies gas of the metal oxide resist material and gas of the inhibitor to the substrate.

8. The substrate treatment method according to claim 7, wherein
the (B) supplies the gas of the inhibitor to the substrate under a nitrogen atmosphere.

9. The substrate treatment method according to claim 1, further comprising
(D) developing the substrate on which the resist film has been formed and which has been subjected to exposure processing and a heat treatment after the exposure processing, with a halogen gas or gas of an acetic acid.

10. The substrate treatment method according to claim 1, further comprising
(E) developing the substrate on which the resist film has been formed and which has been subjected to exposure processing, a heat treatment after the exposure processing and ultraviolet irradiation processing, with a tetraethylammonium hydroxide aqueous solution.

11. A substrate treatment apparatus, comprising:
a first supplier configured to supply a metal oxide resist material containing at least any one of a cluster in which metals are three-dimensionally bonded and a precursor of the cluster, to a substrate;
a second supplier configured to supply an inhibitor containing metal to the substrate; and
a reactor configured to cause the at least any one of the cluster and the precursor to react with the inhibitor to form a resist film containing a polymer in which metals in the metal oxide resist material are linked in a chain.

12. The substrate treatment apparatus according to claim 11, wherein:
the at least any one of the cluster and the precursor of the cluster has a structure in which one carbon is directly bonded to the metal; and
the inhibitor contains a compound having a structure in which two or more carbons are directly bonded to the metal.

13. The substrate treatment apparatus according to claim 11, wherein:
the first supplier supplies liquid of the metal oxide resist material to the substrate; and
the second supplier supplies liquid of the inhibitor to the substrate.

14. The substrate treatment apparatus according to claim 13, wherein
the second supplier
has a treatment chamber configured to allow an inside thereof to be brought into an inert gas atmosphere, and
supplies liquid of the inhibitor to the substrate housed inside the treatment chamber with the inert gas atmosphere.

15. The substrate treatment apparatus according to claim 11, wherein:
the first supplier supplies liquid of the metal oxide resist material to the substrate; and
the second supplier supplies gas of the inhibitor to the substrate after the first supplier supplies the liquid of the metal oxide resist material to the substrate.

16. The substrate treatment apparatus according to claim 15, wherein
the second supplier
has a treatment chamber configured to allow an inside thereof to be brought into an inert gas atmosphere, and
supplies the gas of the inhibitor to the substrate housed inside the treatment chamber with the inert gas atmosphere.

17. The substrate treatment apparatus according to claim 11, wherein:
each of the first supplier and the second supplier has a treatment chamber;
the first supplier supplies gas of the metal oxide resist material to the substrate housed inside the treatment chamber; and
the second supplier supplies gas of the inhibitor to the substrate housed inside the treatment chamber.

18. The substrate treatment apparatus according to claim 17, wherein:
the treatment chamber of the second supplier is configured to allow an inside thereof to be brought into an inert gas atmosphere; and
the second supplier supplies the gas of the inhibitor to the substrate housed inside the treatment chamber with the inert gas atmosphere.

19. The substrate treatment apparatus according to claim 11, further comprising
a developer configured to develop the substrate on which the resist film has been formed and which has been subjected to exposure processing and a heat treatment after the exposure processing, with gas containing halogen or gas of an acetic acid.

20. The substrate treatment apparatus according to claim 11, further comprising
a developer configured to develop the substrate on which the resist film has been formed and which has been subjected to exposure processing, a heat treatment after the exposure processing and ultraviolet irradiation processing, with a tetraethylammonium hydroxide aqueous solution.
